(19) United States
(12) Patent Application Publication
(10) Pub. No.: US 2004/0262599 A1
(43) Pub. Date: Dec. 30, 2004

(54) Organic field effect transistor, method for production and use thereof in the assembly of integrated circuits

(76) Inventors: Adolf Bernds, Baiersdorf (DE); Walter Fix, Nurnberg (DE)

Correspondence Address: William Squire, Carella Byrne Bain Gilfillan Cecchi, Stewart & Olstein, 5 Becker Farm Road, Roseland, NJ, 07068, US

(21) Appl. No.: 10/479,234

(22) PCT Filed: May 27, 2002
(86) PCT No.: PCT/DE02/01948

(30) Foreign Application Priority Data
Jun. 1, 2001 (DE) 101 26 860.2

(51) Int. Cl. H01L 35/24; H01L 21/00

(52) U.S. Cl. 257/40; 438/82; 438/99

(57) ABSTRACT

The invention relates to an OFET, in which the gate (2) and source and drain electrodes (5) are embedded in the insulation layer (3). The A structuring of the insulation layer is carried out by means of a stamping technique, with which high resolution conducting structures can be produced and the OFET has a high power capacity.

The invention relates to an organic field effect transistor (OFET), a method for the production thereof as well as the use of said OFET in the assembly of integrated circuits.

Field effect transistors (OFETs) play a central role in all areas of electronics. Several organic layers must be structured on top of each other to produce said OFETs. The possibilities to accomplish this by means of conventional photolithography, which actually serves to structure inorganic materials, are very limited. The steps customary in the photolithography process affect or dissolve the organic layers and thus render them useless. This occurs, for example, during spin coating, developing and stripping of photosensitive resist.

An important factor for the quality of an OFET and thus an integrated circuit assembled thereof, however, is the integrity and stability of the individual functional layers. In particular, a high resolution or the quality of the source and drain electrodes are essential for the power capacity.

A stamping technique was already proposed to develop the finest structured functional layers on a substrate, with which impressions are stamped and preserved in a layer by means of a respective surface-structured stamp. Said impressions are then filled with the material of the following functional layer. Such a method and OFETs generated thereof are described in the applicant's German patent application DE 10061297.0. However, here the impressions are generated in an additional layer.

It is the purpose of the present invention to specify a simplified, compact OFET assembly permitting its cost-effective production on a mass production scale. In doing so, the power capacity and stability of the OFET is to be ensured at the same time.

The object of the present invention is an organic field effect transistor, comprising

a gate electrode

an insulation layer

a semiconducting layer,

on a substrate, in the preceding sequence, in which the source and drain electrodes and gate electrode are embedded in the insulation layer.

The advantage of the OFET structured in accordance with the invention is the substantial simplification of the transistor assembly, the improved quality of the insulator and the possibility of placing the semiconducting layer on top. The latter is particularly advantageous, since the semiconducting materials or layers represent the most sensitive components in such a system. In other words, the semiconducting layer is no longer exposed to additional process steps. Furthermore, compared with conventional OFETs, an entire layer is eliminated, ultimately making the OFET thinner as compared with the state of the art. In particular, one process step to generate the additional layer is dispensed with.

Preferably, the insulation layer is formed of a self-setting or an ultraviolet or thermosetting polymeric material and structured by means of a stamping technique to accommodate the source and drain electrode(s). For this purpose, the desired structuring for the arrangement of the source and drain electrode(s) is developed on a stamp with a positive charge, and is thereby transferred to the unhardened insulation layer. The structure is preserved through hardening. By applying the stamping technique in accordance with the invention in conjunction with the hardening of the insulation material, the finest, discrete and permanent traces or impressions can be generated for the strip tracks or electrodes.

This also guarantees, in accordance with the invention, that the distance 1 between source and drain electrodes is smaller than 20 μm, in particular, smaller than 10 μm and preferably between 2 and 5 μm, which corresponds to the highest resolution and thus the highest power capacity of an OFET.

The present invention also relates to a method to produce an OFET with a particular bottom-gate structure, in which a gate electrode is placed on a substrate, an insulation layer made from a hardening material is deposited on top, the structure for the source and drain electrode(s) is generated in the unhardened insulation layer by means of a stamp and preserved by hardening of the insulation material, the preserved structure is filled with a conductive material and the semiconducting layer is formed on top.

As stated, the advantages consist of a simplified transistor assembly. Only one insulation layer is utilized, which simultaneously represents the carrier of the source and drain electrodes and the insulator. In contrast, the normal production process envisions a separate layer for each of the two functions. Eliminating an entire layer not only means savings in material but also cost.

The quality of the insulator has improved. One reason is that the insulator surface is smoothed by the stamping method, in fact, where it is most important for the transistor function, namely, in the contact area of semiconductor and insulator.

The insulator is also optimally preconditioned to accommodate the semiconductor, since it is no longer affected during the application of the semiconductor's solvent as a result of the hardening process. This also means ample liberty in selecting the solvent, in which the semiconductor can be dissolved to deposit and form the layer.

Preferably, the (self-) hardening material for the insulation layer is selected from epoxies and acrylics. Said materials can be conditioned in such a way that they already harden, for example, under the effect of atmospheric oxygen, and/or under the influence of ultraviolet light and/or heat. Such polymers can be deposited from either the solvent or in the form of liquid ultraviolet lacquers through either spin coating or printing, thereby making it possible to ensure great homogeneity of the layer.

The conductive material to develop the electrodes may be selected from conductive organic materials and particle-filled polymers. Doped polyethylene or doped polyaniline, for example, are conductive organic materials. Particle-filled polymers are polymers that contain densely packed, conductive, mostly inorganic particles. The polymer itself can be conductive or non-conductive. Conductive inorganic particles are silver or other metallic particles, for example, as well as graphite or carbon black.

Such conductive material is preferably squeeged to the given structuring of the insulator. The advantage of the squeegee method is that the selection of conductive materials is nearly unlimited, thereby ensuring uniform filling of the structuring.

The method in accordance with the invention may also be arranged in an uninterrupted process, thus ensuring higher productivity.

Since the OFETs embodied in accordance with the invention are of such high quality and power capacity, said OFETs are particularly suitable for the assembly of integrated circuits, which may also be all organic.

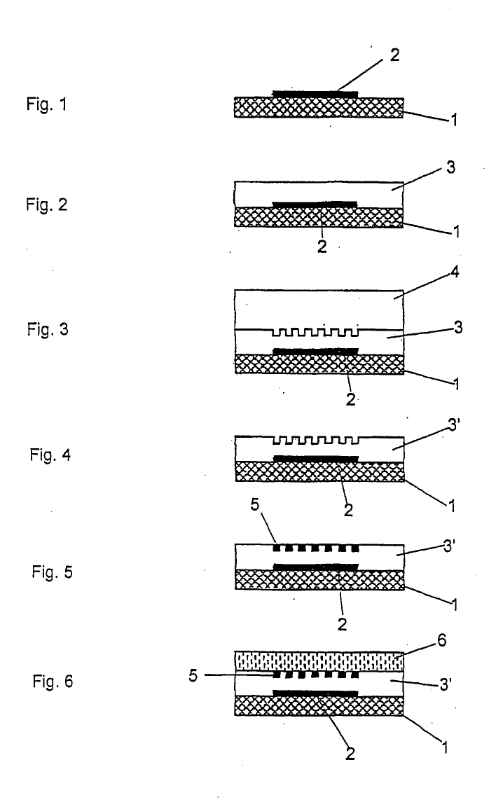

The method in accordance with the invention and the assembly of the OFET in accordance with the invention are described below in greater detail based on schematic FIGS. 1 through 6.

First, in accordance with FIG. 1, a gate electrode 2 is structured on a substrate 1, which, for example, may be a thin glass film or a polyethylene, polyimide or polyethylene terephthalate film. Said gate electrode 2 may consist of metallic or non-metallic organic material. Copper, aluminum, gold or indium tin oxide are considered metallic conductors. Conductive organic materials are doped polyaniline or polyethylene or particle-filled polymers. Depending on the selection of the conductive material, structuring of the gate electrode is effected through either printing or lithographic structuring.

Then, in accordance with FIG. 2, the insulation layer 3 is applied to the substrate 1 via said gate electrode 2. This may be accomplished by spin coating or printing. Preferably, said insulation layer 3 is generated from a UV-hardening or thermosetting material such as epoxy or acrylate.

In accordance with FIG. 3, this desired structure is stamped in said unhardened insulation layer 3 by means of a stamp 4, which carries the structure of the source and drain electrode(s) with a positive charge. Said insulation layer 3 is then left to harden or hardened under the influence of ultraviolet light or heat and said stamp 4 is then removed.

As is apparent from FIG. 4, the structure envisioned for the source and drain electrodes is permanently and acutely preserved in the insulation layer 3′.

In accordance with FIG. 5, the conductive material 5 is now filled into the generated impressions or traces. Based on the advantages specified hereinabove, this is preferably accomplished by means of a squeegee. Materials suitable for this purpose are also mentioned hereinabove.

In accordance with FIG. 6, the semiconducting layer remains to be applied, which may be processed from of a solution of conjugated polymers such as polythiophene, polythienylene or polyfluoro derivatives. The application may be effected by spin coating, printing or the use of a squeegee. So-called small molecules are also suitable for the assembly of the semiconducting layer, namely oligomeres like sexithiophene or pentacene, which are deposited on the substrate by vacuum technology.

Due to the insensitivity of the hardened insulation layer, a great variety of solvents can be selected for the application of the semiconducting layer, and thus the most suitable application technology for the entire production method, in each case.

The proposed production method is appropriate for commercial production. Many different OFETs can simultaneously be generated by an uninterrupted method on a continuous belt.

1. An organic field effect transistor comprising
a gate electrode (2)
an insulation layer (3′)
a semiconducting layer (6),
on a substrate (1), in the preceding sequence, in which the source and drain electrode(s) are embedded in the insulation layer (3′).

2. An organic field effect transistor in accordance with claim 1, characterized in that said insulation layer (3′) consists of an ultraviolet or thermosetting material.

3. An organic field effect transistor in accordance with claims 1 or 2, characterized in that said insulation layer (3′) is structured to accommodate the source and drain electrode(s) by means of a stamping technique.

4. An organic field effect transistor in accordance with one of the claims 1 through 3, characterized in that the distance 1 between source and drain electrodes is smaller than 20 μm, in particular smaller than 10 μm and preferably between 2 and 5 μm.

5. A method for the production of an OFET with bottom-gate structure in accordance with one of the claims 1 through 4, in which a gate electrode (2) is applied to a substrate (1), an insulation layer (3) made of a hardening material is formed above, the structure for the source and drain electrode(s) is generated in said unhardened insulation layer (3) by means of a stamp (4) and preserved through hardening of the insulation material, the preserved structure is filled with a conductive material and the semiconducting layer (6) is formed on top.

6. A method in accordance with claim 5 characterized in that the hardened material for said insulating layer (3′) is selected from expoxies and/or acrylates.

7. A method in accordance with claim 5 or 6 characterized in that the conducting material for the formation of electrodes is selected from conducting organic materials and particle-filled polymers.

8. A method in accordance with one of the claims 5 through 7 characterized in that the conducting material is squeegeed into the predetermined structure for said insulator (3′).

9. A method in accordance with one of the claims 5 through 8, which is carried out as a continuous method with a continuous belt.

10. Use of an OFET in accordance with one of the claims 1 through 4 or 5 through 9 in the assembly of integrated circuits.
